(19) United States
(12) Patent Application Publication
(10) Pub. No.: US 2011/0221310 A1
(43) Pub. Date: Sep. 15, 2011

(54) METHOD OF MANUFACTURING PACKAGE, PIEZOELECTRIC VIBRATOR, OSCILLATOR, ELECTRONIC APPARATUS, AND RADIO-CONTROLLED TIMEPIECE

(76) Inventor: Yoshihiro Kusanagi, Chiba-shi (JP)

(21) Appl. No.: 13/047,225

(22) Filed: Mar. 14, 2011

(30) Foreign Application Priority Data
Mar. 15, 2010 (JP) 2010-058432

(51) Int. Cl. H03B 1/00; H01L 41/053; H01L 41/08; G04F 5/06; H01L 41/22

(52) U.S. Cl. 310/344; 331/156; 368/159; 29/25.35

(57) ABSTRACT

Provided are a method of manufacturing a package capable of forming a penetration electrode without conduction defects while maintaining the airtightness of a cavity, a piezoelectric vibrator manufactured by the manufacturing method, and an oscillator, an electronic apparatus, and a radio-controlled timepiece each having the piezoelectric vibrator. A penetration electrode forming step includes: a penetration hole forming step of forming a penetration hole in a base substrate wafer (first substrate); a first paste material filling step of filling a first paste material in the penetration hole and temporarily drying the first paste material; and a second paste material filling step of filling a second paste material in the penetration hole so as to be overlapped on the first paste material. The first paste material has a viscosity lower than the second paste material.

### RELATED APPLICATIONS

This application claims priority under 35 U.S.C. §119 to Japanese Patent Application No. 2010-058432 filed on Mar. 15, 2010, the entire content of which is hereby incorporated by reference.

### BACKGROUND OF THE INVENTION

1. Field of the Invention

The present invention relates to a method of manufacturing a package, a piezoelectric vibrator, and an oscillator, an electronic apparatus, and a radio-controlled timepiece each having the piezoelectric vibrator.

2. Description of the Related Art

Recently, a piezoelectric vibrator utilizing quartz or the like has been used in cellular phones and portable information terminals as the time source, the timing source of a control signal, a reference signal source, and the like. Although there are various piezoelectric vibrators of this type, a surface mounted device-type piezoelectric vibrator is known as one example thereof. As the piezoelectric vibrator of this type, a three-layered piezoelectric vibrator in which a piezoelectric substrate having a piezoelectric vibrating reed formed thereon is interposed between first and second substrates is known. In this case, the piezoelectric vibrating reed is accommodated in a cavity (sealed space) that is formed between the base substrate and the lid substrate.

Moreover, in recent years, instead of the three-layered piezoelectric vibrator, a two-layered piezoelectric vibrator has also been developed. The piezoelectric vibrator of this type has a two-layered structure in which a base substrate and a lid substrate are directly bonded and packaged, and a piezoelectric vibrating reed is accommodated in a cavity formed between the two substrates. The packaged two-layered piezoelectric vibrator is ideally used as it is superior in achieving a thin profile compared with the three-layered structure. As an example of such a two-layered piezoelectric vibrator, a piezoelectric vibrator in which piezoelectric vibrating reeds sealed in a cavity and outer electrodes formed on the outer side of the base substrate are electrically connected by penetration electrodes formed on the base substrate is known (for example, see JP-A-2002-124845 and JP-A-2006-279872).

In the two-layered piezoelectric vibrator, the penetration electrodes perform two major roles of electrically connecting the piezoelectric vibrating reeds and the outer electrodes to each other and blocking the penetration holes to maintain the airtightness of the cavity. Particularly, if the contact between the penetration electrode and the penetration hole is not sufficient, there is a possibility that the airtightness of the cavity is impaired. In order to eliminate such a problem, it is necessary to form the penetration electrode in a state where the penetration electrode is tightly and closely adhered to the inner circumferential surface of the penetration hole to completely block the penetration hole, and no depression appears on the surface.

JP-A-2002-124845 and JP-A-2006-279872 describes that the penetration electrode is formed using a conductive paste material (an Ag paste material, an Au—Sn paste material, or the like). However, there is no description as to a specific manufacturing method such as how to form the penetration electrode.

In general, it is necessary to perform baking to cure a conductive paste material after it is filled in the penetration electrode. However, when the baking is performed, since a solvent or a dispersion medium (hereinafter referred to as a “solvent or the like”) included in the conductive paste material disappears by evaporation, the volume of the conductive paste material after the baking generally decreases compared to the volume of the conductive paste material before the baking. Therefore, even when the penetration electrode is formed using the conductive paste material, there is a possibility that depressions appear on the surface. As a result, there is a possibility that the conduction between the piezoelectric vibrating reed and the outer electrode is impaired.

The conduction defects caused by the occurrence of depressions may be solved by forming the penetration electrode using a conductive paste material in which the compounding ratio of a conductive member such as Ag or Au—Sn is high whereas the compounding ratio of a solvent or the like is low. According to the conductive paste material, since the amount of the solvent or the like evaporated during the baking is small, it is possible to suppress the occurrence of depressions on the surface of the penetration electrode and secure reliable conduction of the penetration electrode.

However, since the compounding ratio of the conductive member in the conductive paste material is high, the viscosity thereof increases. Therefore, when the conductive paste material is filled in the penetration hole, the conductive paste material may not be dispersed over a wide area to every corner, and voids may be formed inside the conductive paste material and between the inner circumferential surface of the penetration hole and the conductive paste material. Moreover, when the conductive paste material is baked in such a state where voids are present to form the penetration electrode, adhesion of the conductive paste material is insufficient, and the airtightness of the cavity may be impaired.

As another method of solving the conduction defects caused by the occurrence of depressions, a method of forming the penetration electrode using a conductive rivet member and a glass frit is proposed. According to a specific method of forming the penetration electrode, first, a rivet member having a planar base portion and a core portion assembled on the surface of the base portion along the normal direction is inserted into the penetration hole, and a glass frit is filled in the gap between the penetration hole and the core portion. After the filled glass frit is baked so that the penetration hole, the core portion, and the glass frit are integrated with each other, the base portion of the rivet member is polished and removed, whereby the penetration electrode is formed. In this way, since the base substrate, the glass frit, and the core portion can be made flush with each other, it is possible to suppress the occurrence of depressions on the surface of the penetration electrode and secure reliable conduction of the penetration electrode.

However, since the rivet member is inserted and disposed in the penetration hole, the gap between the penetration hole and the core portion is very narrow. Therefore, the glass frit may not be dispersed over a wide area to every corner of the gap, and the voids may be formed inside the glass frit, and between the outer circumferential surface of the core portion and the glass frit, and between the inner circumferential surface of the penetration hole and the glass frit. When the glass frit is baked in such a state where the voids are present to form the penetration electrode, similarly to the case of forming the penetration electrode using the conductive paste material, the airtightness of the cavity may be impaired.

### SUMMARY OF THE INVENTION

Therefore, an object of the present invention is to provide a method of manufacturing a package capable of forming a penetration electrode without conduction defects while maintaining the airtightness of a cavity, a piezoelectric vibrator manufactured by the manufacturing method, and an oscillator, an electronic apparatus, and a radio-controlled timepiece each having the piezoelectric vibrator.

According to an aspect of the present invention, there is provided a method of manufacturing a package capable of sealing an electronic component in a cavity which is formed between a plurality of substrates bonded to each other, the method including a penetration electrode forming step of forming a penetration electrode so as to penetrate a first substrate of the plurality of substrates in a thickness direction thereof so that the inner side of the cavity and the outer side of the package are electrically connected to each other. The penetration electrode forming step includes a penetration hole forming step of forming a penetration hole in the first substrate; a first paste material filling step of filling a first paste material in the penetration hole and temporarily drying the first paste material; and a second paste material filling step of filling a second paste material in the penetration hole to be overlapped on the first paste material, and the first paste material has a viscosity lower than the second paste material.

According to this configuration, since the first paste material having a low viscosity is filled first, the first paste material can be dispersed over a wide area to every corner of the inner portion of the penetration hole. Therefore, since the occurrence of voids in the penetration electrode can be suppressed, it is possible to maintain the airtightness of the cavity in a favorable state. However, since the ratio of a solvent or the like compounded in the first paste material having a low viscosity is high, the decrease in its volume during curing is large. In contrast, according to this configuration, the second paste material having a high viscosity is filled so as to be overlapped on the first paste material. The ratio of a solvent or the like compounded in the second paste material is low as compared to the first paste material, and the decrease in its volume during curing is small. Therefore, it is possible to suppress the occurrence of depressions on the surface of the penetration electrode after curing and form the penetration electrode without conduction defects.

In the package manufacturing method, it is preferable that a hole diameter of a first opening of the penetration hole on a first surface side of the first substrate is larger than a hole diameter of a second opening of the penetration hole on a second surface side of the first substrate, and the first and second paste materials are filled in the penetration hole from the first opening.

According to this configuration, since the first and second paste materials are filled from the first opening having a large hole diameter, the first and second paste materials can be easily filled in the inner portion of the penetration hole. Moreover, since the hole diameter decreases from the first surface side towards the second surface side, it is difficult for the paste material to be filled to every corner of the inner portion of the penetration hole. In contrast, according to this configuration, since the first paste material having a low viscosity is filled first, the first paste material can be dispersed over a wide area to every corner of the inner portion of the penetration hole. In this way, since the occurrence of voids in the penetration electrode can be suppressed, it is possible to maintain the airtightness of the cavity in a favorable state.

In the package manufacturing method, it is preferable that the method includes a rivet member disposing step, prior to the first paste material filling step, of inserting a core portion of a conductive rivet member, which includes a planar base portion and the core portion assembled on the surface of the base portion along a normal direction, into the penetration hole.

According to this configuration, since the core portion of the conductive rivet member is disposed in the penetration hole, it is possible to secure reliable conduction of the penetration electrode. However, when the core portion is inserted into the penetration hole, the gap between the penetration hole and the core portion narrows, thus making it difficult to fill the paste material into the gap. In contrast, according to this configuration, since the first paste material having a low viscosity is filled after the core portion is disposed in the penetration hole, the first paste material can be dispersed over a wide area to every corner of the gap between the penetration hole and the core portion. In this way, since the occurrence of voids in the penetration electrode can be suppressed, it is possible to maintain the airtightness of the cavity in a favorable state.

According to another aspect of the present invention, there is provided a piezoelectric vibrator in which a piezoelectric vibrating reed is sealed in the cavity of the package manufactured by the package manufacturing method as the electronic component.

According to this configuration, since the piezoelectric vibrator is sealed in the package which is manufactured by a manufacturing method capable of securing reliable conduction of the penetration electrode while maintaining the airtightness of the cavity, a piezoelectric vibrator having excellent performance and superior reliability can be provided.

According to still another aspect of the invention, there is provided an oscillator in which the above-described piezoelectric vibrator is electrically connected to an integrated circuit as an oscillating piece.

According to still another aspect of the invention, there is provided an electronic apparatus in which the above-described piezoelectric vibrator is electrically connected to a clock section.

According to still another aspect of the invention, there is provided a radio-controlled timepiece in which the above-described piezoelectric vibrator is electrically connected to a filter section.

Since each of the oscillator, electronic apparatus, and radio-controlled timepiece of the above aspects of the present invention includes the piezoelectric vibrator which is manufactured by a manufacturing method capable of securing reliable conduction of the penetration electrode while maintaining the airtightness of the cavity, an oscillator, an electronic apparatus, and a radio-controlled timepiece having excellent performance and superior reliability can be provided.

According to this configuration, since the first paste material having a low viscosity is filled first, the first paste material can be dispersed over a wide area to every corner of the inner portion of the penetration hole. Therefore, since the occurrence of voids in the penetration electrode can be suppressed, it is possible to maintain the airtightness of the cavity in a favorable state. However, since the ratio of a solvent or the like compounded in the first paste material having a low viscosity is high, the decrease in its volume during curing is large. In contrast, according to this configuration, the second paste material having a high viscosity is filled so as to be overlapped on the first paste material. The ratio of a solvent or the like compounded in the second paste material is low as compared to the first paste material, and the decrease in its volume during curing is small. Therefore, it is possible to suppress the occurrence of depressions on the surface of the penetration electrode after curing and form the penetration electrode without conduction defects.

### BRIEF DESCRIPTION OF THE DRAWINGS

FIG. 1 is a perspective view showing an external appearance of a piezoelectric vibrator according to an embodiment of the present invention.

FIG. 2 is a top view showing an inner structure of the piezoelectric vibrator shown in FIG. 1, showing a state where a lid substrate is removed.

FIG. 3 is a sectional view of the piezoelectric vibrator taken along the line A-A in FIG. 2.

FIG. 4 is an exploded perspective view of the piezoelectric vibrator shown in FIG. 1.

FIG. 5 is a top view of a piezoelectric vibrating reed.

FIG. 6 is a bottom view of the piezoelectric vibrating reed.

FIG. 7 is a sectional view taken along the line B-B in FIG. 5.

FIG. 8 is a flowchart of the manufacturing method of a piezoelectric vibrator.

FIG. 9 is an exploded perspective view of a wafer assembly.

FIG. 10 is a diagram illustrating a penetration hole.

FIGS. 11A and 11B are diagrams illustrating a rivet member, in which

FIG. 11A is a perspective view and FIG. 11B is a sectional view taken along the line C-C in FIG. 11A.

FIGS. 12A and 12B are diagrams illustrating a rivet member disposing step, in which FIG. 12A shows a state during the disposing and FIG. 12B shows a state after the disposing.

FIGS. 13A and 13B are diagrams illustrating a first paste material filling step, in which FIG. 13A shows a state where a first paste material is being filled and FIG. 13B shows a state after the paste material is temporarily dried.

FIGS. 14A and 14B are diagrams illustrating a second paste material filling step, in which FIG. 14A shows a state where a second paste material is being filled and FIG. 14B shows a state after the paste material is temporarily dried.

FIG. 15 is a view showing the configuration of an oscillator according to an embodiment of the present invention.

FIG. 16 is a view showing the configuration of an electronic apparatus according to an embodiment of the present invention.

FIG. 17 is a view showing the configuration of a radio-controlled timepiece according to an embodiment of the present invention.

### DETAILED DESCRIPTION OF THE PREFERRED EMBODIMENTS

### Piezoelectric Vibrator

Hereinafter, a piezoelectric vibrator according to an embodiment of the present invention will be described with reference to the drawings.

In the following description, it is assumed that a first substrate is a base substrate, and a substrate bonded to the base substrate is a lid substrate. Moreover, it is assumed that an outer surface of the base substrate of a package (a piezoelectric vibrator) is a first surface L, and a bonding surface on the opposite side of the base substrate bonded to the lid substrate is a second surface U.

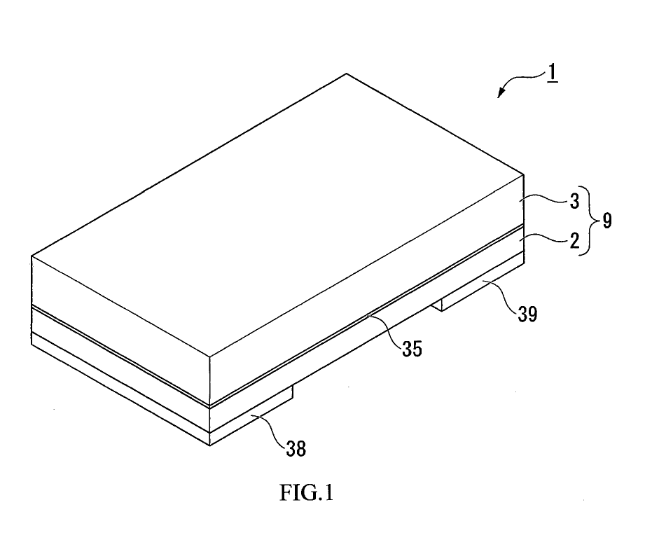

FIG. 1 is a perspective view showing an external appearance of a piezoelectric vibrator according to an embodiment of the present invention.

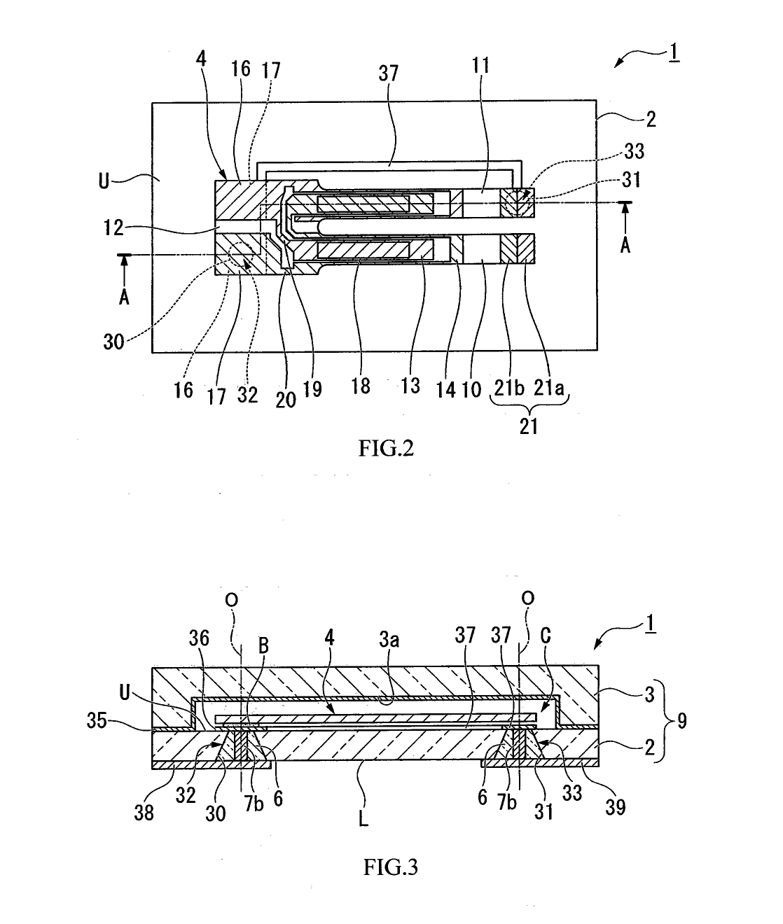

FIG. 2 is a top view showing an inner structure of the piezoelectric vibrator shown in FIG. 1, showing a state where a lid substrate is removed.

FIG. 3 is a sectional view of the piezoelectric vibrator taken along the line A-A in FIG. 2.

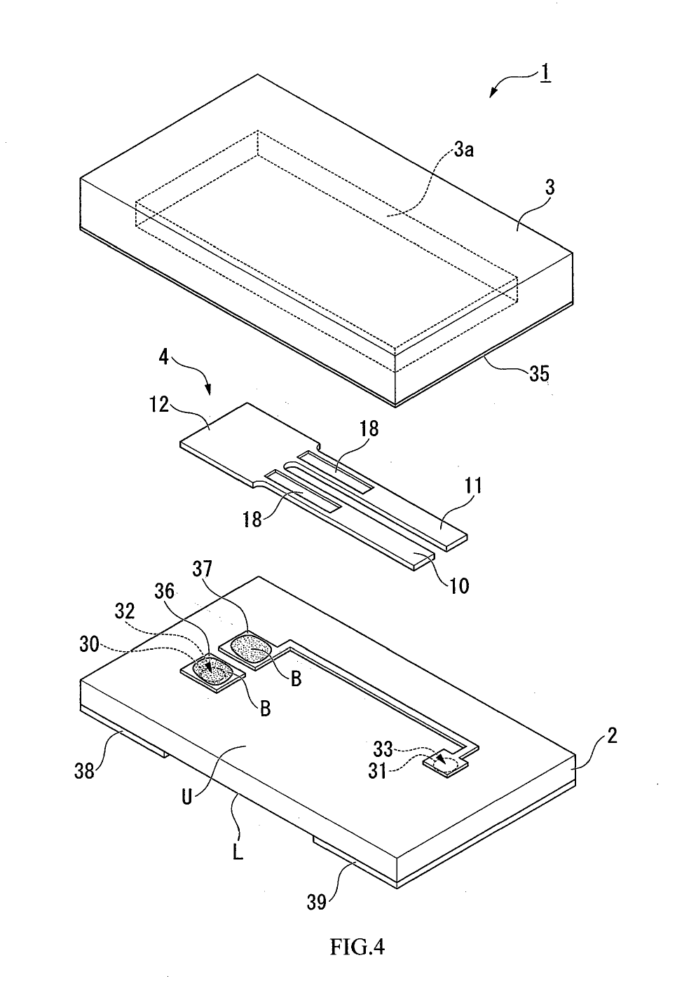

FIG. 4 is an exploded perspective view of the piezoelectric vibrator shown in FIG. 1.

In FIG. 4, for better understanding of the drawings, illustrations of the excitation electrode 15, extraction electrodes 19 and 20, mount electrodes 16 and 17, and weight metal film 21, which will be described later, are omitted.

As shown in FIGS. 1 to 4, a piezoelectric vibrator 1 according to the present embodiment is a surface mounted device-type piezoelectric vibrator 1 which includes a package 9, in which a base substrate 2 and a lid substrate 3 are anodically bonded to each other with a bonding film 35 disposed therebetween, and a piezoelectric vibrating reed 4 which is accommodated in a cavity C of the package 9.

### Piezoelectric Vibrating Reed

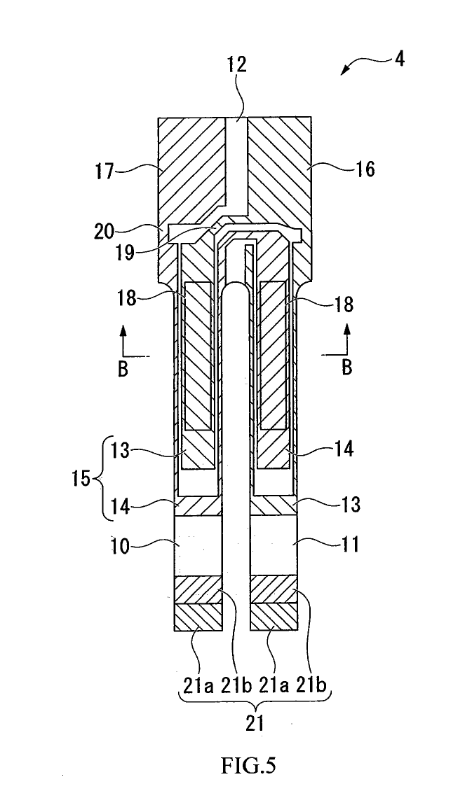

FIG. 5 is a top view of a piezoelectric vibrating reed.

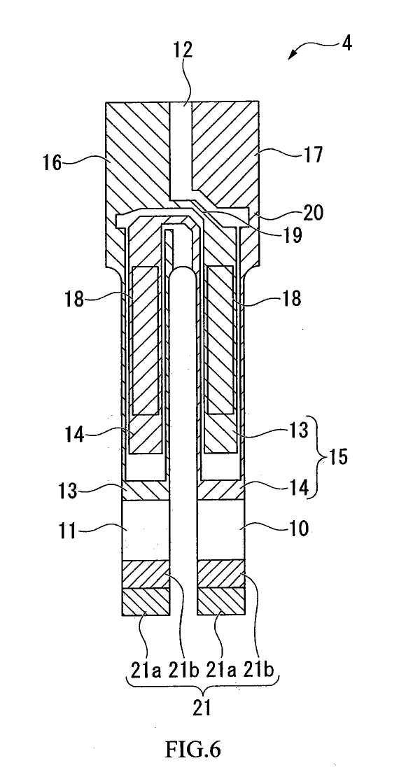

FIG. 6 is a bottom view of the piezoelectric vibrating reed.

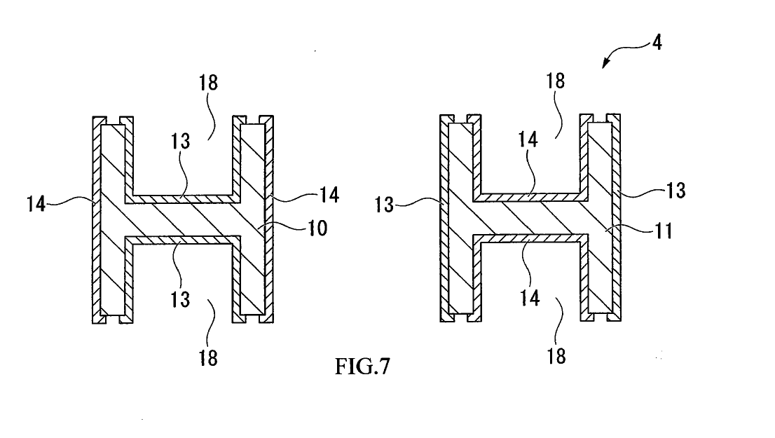

FIG. 7 is a sectional view taken along the line B-B in FIG. 5.

As shown in FIGS. 5 to 7, the piezoelectric vibrating reed 4 is a turning-fork type vibrating reed which is made of a piezoelectric material such as crystal, lithium tantalate, or lithium niobate and is configured to vibrate when a predetermined voltage is applied thereto. The piezoelectric vibrating reed 4 includes a pair of vibrating arms 10 and 11 disposed in parallel to each other, a base portion 12 to which the base end sides of the pair of vibrating arms 10 and 11 are integrally fixed, and groove portions 18 which are formed on both principal surfaces of the pair of vibrating arms 10 and 11. The groove portions 18 are formed so as to extend from the base end sides of the vibrating arms 10 and 11 along the longitudinal direction of the vibrating arms 10 and 11 up to approximately the middle portions thereof.

The piezoelectric vibrating reed 4 includes: an excitation electrode 15 which is formed on the outer surfaces of the base ends of the pair of vibrating arms 10 and 11 so as to allow the pair of vibrating arms 10 and 11 to vibrate and includes a first excitation electrode 13 and a second excitation electrode 14; and mount electrodes 16 and 17 which are electrically connected to the first excitation electrode 13 and the second excitation electrode 14, respectively. The excitation electrode 15, mount electrodes 16 and 17, and extraction electrodes 19 and 20 are formed by a coating of a conductive film of chromium (Cr), nickel (Ni), aluminum (Al), and titanium (Ti) or the like, for example.

The excitation electrode 15 is an electrode that allows the pair of vibrating arms 10 and 11 to vibrate at a predetermined resonance frequency in a direction moving closer to or away from each other. The first excitation electrode 13 and second excitation electrode 14 that constitute the excitation electrode 15 are patterned and formed on the outer surfaces of the pair of vibrating arms 10 and 11 in an electrically isolated state. Specifically, the first excitation electrode 13 is mainly formed on the groove portion 18 of one vibrating arm 10 and both side surfaces of the other vibrating arm 11. On the other hand, the second excitation electrode 14 is mainly formed on both side surfaces of one vibrating arm 10 and the groove portion 18 of the other vibrating arm 11. Moreover, the first excitation electrode 13 and the second excitation electrode 14 are electrically connected to the mount electrodes 16 and 17 via the extraction electrodes 19 and 20, respectively, on both principal surfaces of the base portion 12.

Furthermore, the tip ends of the vibrating arms 10 and 11 are coated with a weight metal film 21 for mass adjustment of their own vibration states (tuning the frequency) in a manner such as to vibrate within a predetermined frequency range. The weight metal film 21 is divided into a rough tuning film 21a used for tuning the frequency roughly and a fine tuning film 21b used for tuning the frequency finely. By tuning the frequency with the use of the rough tuning film 21a and the fine tuning film 21b, the frequency of the pair of the vibrating arms 10 and 11 can be set to fall within the range of the nominal frequency of the device.

### Package

As shown in FIGS. 1, 3, and 4, the lid substrate 3 is a substrate that can be anodically bonded and that is made of a glass material, for example, soda-lime glass, and is formed in an approximately plate-like form. On a bonding surface side of the lid substrate 3 to be bonded to the base substrate 2, a recess portion 3a for a cavity C is formed in which the piezoelectric vibrating reed 4 is accommodated.

A bonding film 35 for anodic bonding is formed on the entire surface on the bonding surface side of the lid substrate 3 to be bonded to the base substrate 2. That is to say, the bonding film 35 is formed in a frame region at the periphery of the recess portion 3a in addition to the entire inner surface of the recess portion 3a. Although the bonding film 35 of the present embodiment is made of a Si film, the bonding film 35 may be made of Al. As will be described later, the bonding film 35 and the base substrate 2 are anodically bonded, whereby the cavity C is vacuum-sealed.

The base substrate 2 is a substrate that is made of a glass material, for example, soda-lime glass, and is formed in an approximately plate-like form having the same outer shape as the lid substrate 3 as shown in FIGS. 1 to 4.

Moreover, the base substrate 2 is formed with a pair of penetration holes 30 and 31 penetrating through the base substrate 2 in the thickness direction thereof and a pair of penetration electrodes 32 and 33.

As shown in FIGS. 2 and 3, the penetration holes 30 and 31 are formed so as to be received in the cavity C when the piezoelectric vibrator 1 is formed. More specifically, the penetration holes 30 and 31 of the present embodiment are formed such that one penetration hole 30 is positioned at a corresponding position close to the base portion 12 of the mounted piezoelectric vibrating reed 4 which is mounted in a mounting step described later, and the other penetration hole 31 is positioned at a corresponding position close to the tip end sides of the vibrating arms 10 and 11. As shown in FIG. 3, the penetration holes 30 and 31 of the present embodiment are formed so that the inner shape thereof gradually increases from the second surface U side towards the first surface L side and the cross section including the central axis O of the penetration holes 30 and 31 has a tapered shape. Moreover, in the present embodiment, the cross section in the direction perpendicular to the central axis O of the penetration holes 30 and 31 has a circular shape.

As shown in FIG. 3, the penetration electrodes 32 and 33 are formed by a cylindrical member 6 which is disposed at the inner side of the penetration holes 30 and 31 and a core portion 7b of a rivet member.

In the present embodiment, the cylindrical member 6 is obtained by baking first and second paste materials made from a glass frit described later. Specifically, the small-diameter portion (the second surface U side) of the cylindrical member 6 is formed by baking the first paste material, and the large-diameter portion (the first surface L side) thereof is formed by baking the second paste material. The cylindrical member 6 has a shape in which both ends are flat and which has approximately the same thickness as the base substrate 2. The core portion 7b is disposed at the center of the cylindrical member 6 so as to penetrate through the cylindrical member 6. The core portion 7b is formed by polishing the base portion of the rivet member described later. Moreover, the cylindrical member 6 is tightly attached to the core portion 7b and the penetration holes 30 and 31. The cylindrical member 6 and the core portion 7b serve to maintain the airtightness of the cavity C by completely blocking the penetration holes 30 and 31 and also to make lead-out electrodes 36 and 37 and outer electrodes 38 and 39 described later electrically connected to each other.

As shown in FIGS. 2 to 4, a pair of lead-out electrodes 36 and 37 is patterned on the second surface U side of the base substrate 2. One lead-out electrode 36 among the pair of lead-out electrodes 36 and 37 is formed so as to be disposed right above one penetration electrode 32. Moreover, the other lead-out electrode 37 is formed so as to be disposed right above the other penetration electrode 33 after being led out from a position near one lead-out electrode 36 towards the tip end sides of the vibrating arms 10 and 11 along the vibrating arms 10 and 11.

Moreover, bumps B are formed on the pair of lead-out electrodes 36 and 37, and the pair of mount electrodes of the piezoelectric vibrating reed 4 is mounted using the bumps B. In this way, one mount electrode 16 of the piezoelectric vibrating reed 4 is electrically connected to one penetration electrode 32 via one lead-out electrode 36, and the other mount electrode 17 is electrically connected to the other penetration electrode 33 via the other lead-out electrode 37.

Moreover, as shown in FIGS. 1, 3, and 4, a pair of outer electrodes 38 and 39 is formed on the first surface L of the base substrate 2. The pair of outer electrodes 38 and 39 is formed at both ends in the longitudinal direction of the base substrate 2 and is electrically connected to the pair of penetration electrodes 32 and 33, respectively.

When the piezoelectric vibrator 1 configured in this manner is operated, a predetermined drive voltage is applied to the outer electrodes 38 and 39 formed on the base substrate 2. In this way, a current can be made to flow to the excitation electrode 15 including the first and second excitation electrodes 13 and 14, of the piezoelectric vibrating reed 4, and the pair of vibrating arms 10 and 11 is allowed to vibrate at a predetermined frequency in a direction moving closer to or away from each other. This vibration of the pair of vibrating arms 10 and 11 can be used as the time source, the timing source of a control signal, the reference signal source, and the like.

### Piezoelectric Vibrator Manufacturing Method

Next, a method of manufacturing the above-described piezoelectric vibrator will be described with reference to a flowchart.

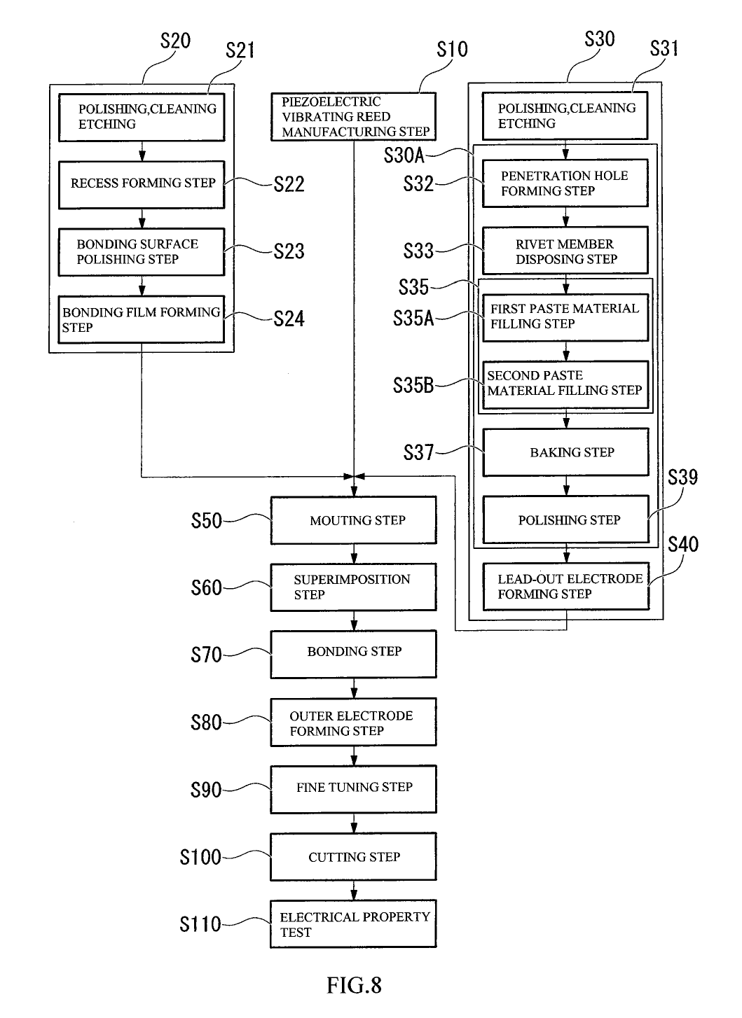

FIG. 8 is a flowchart of the manufacturing method of a piezoelectric vibrator according to the present embodiment.

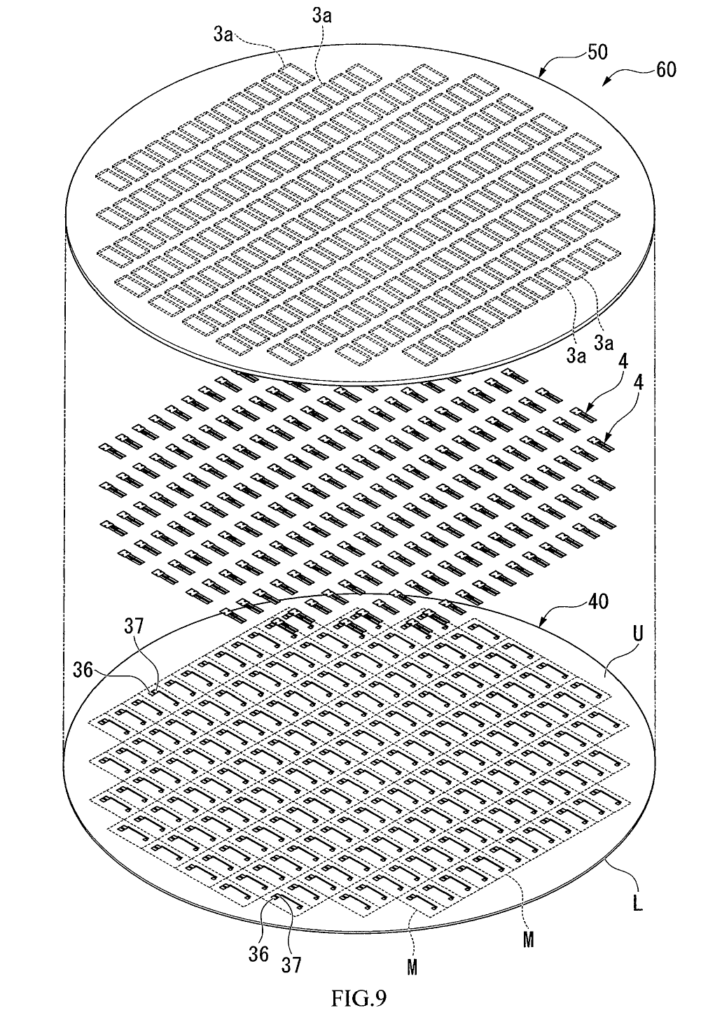

FIG. 9 is an exploded perspective view of a wafer assembly. The dotted line shown in FIG. 9 is a cutting line M along which a cutting step performed later is achieved.

The manufacturing method of the piezoelectric vibrator according to the present embodiment mainly includes a piezoelectric vibrating reed manufacturing step S10, a lid substrate wafer manufacturing step S20, a base substrate wafer manufacturing step S30, and an assembling step (S50 and subsequent steps). Among these steps, the piezoelectric vibrating reed manufacturing step S10, the lid substrate wafer manufacturing step S20, and the base substrate wafer manufacturing step S30 can be performed in parallel. Moreover, the package manufacturing method includes at least the lid substrate wafer manufacturing step S20, the base board wafer manufacturing step S30, and a bonding step S70 of the assembling step.

### Piezoelectric Vibrating Reed Manufacturing Step

In the piezoelectric vibrating reed manufacturing step S10, the piezoelectric vibrating reed 4 shown in FIGS. 5 to 7 is manufactured. Specifically, first, a rough crystal Lambert is sliced at a predetermined angle to obtain a wafer having a constant thickness. Subsequently, the wafer is subjected to crude processing by lapping, and an affected layer is removed by etching. Then, the wafer is subjected to mirror processing such as polishing to obtain a wafer having a predetermined thickness. Subsequently, the wafer is subjected to appropriate processing such as washing, and the wafer is patterned so as to have the outer shape of the piezoelectric vibrating reed 4 by a photolithography technique. Moreover, a metal film is formed and patterned on the wafer, thus forming the excitation electrode 15, the extraction electrodes 19 and 20, the mount electrodes 16 and 17, and the weight metal film 21. In this way, a plurality of piezoelectric vibrating reeds 4 can be manufactured. Subsequently, rough tuning of the resonance frequency of the piezoelectric vibrating reed 4 is performed. This rough tuning is achieved by irradiating the rough tuning film 21a of the weight metal film 21 with a laser beam to evaporate a part of the rough tuning film 21a, thus changing the weight of the vibrating arms 10 and 11.

### Lid Substrate Wafer Manufacturing Step

In the lid substrate wafer manufacturing step S20, as shown in FIG. 9, the lid substrate wafer 50 later serving as the lid substrate is manufactured. First, a disk-shaped lid substrate wafer 50 made of a soda-lime glass is polished to a predetermined thickness and cleaned, and then, the affected uppermost layer is removed by etching or the like (S21). Subsequently, in a recess forming step S22, a plurality of recess portions 3a for cavities is formed on a bonding surface of the lid substrate wafer 50 to be bonded to the base substrate wafer 40. The recess portions 3a for cavities are formed by heat-press molding, etching, or the like. After that, in a bonding surface polishing step S23, the bonding surface bonded to the base substrate wafer 40 is polished.

Subsequently, in a bonding film forming step S24, a bonding film 35 shown in FIGS. 1, 2, and 4 is formed on the bonding surface to be bonded to the base substrate wafer 40. The bonding film 35 may be formed on the entire inner surface of the recess portions 3a in addition to the bonding surface to be bonded to the base substrate wafer 40. In this way, patterning of the bonding film 35 is not necessary, and the manufacturing cost can be reduced. The bonding film 35 can be formed by a film-formation method such as sputtering or CVD. Since the bonding surface polishing step S23 is performed before the bonding film forming step S24, the flatness of the surface of the bonding film 35 can be secured, and stable bonding with the base substrate wafer 40 can be achieved.

### Base Substrate Wafer Manufacturing Step

In a base substrate wafer manufacturing step S30, as shown in FIG. 9, the base substrate wafer 40 later serving as the base substrate is manufactured. First, a disk-shaped base substrate wafer 40 made of a soda-lime glass is polished to a predetermined thickness and cleaned, and then, the affected uppermost layer is removed by etching or the like (S31).

### Penetration Electrode Forming Step

Subsequently, a penetration electrode forming step S30A is performed where the pair of penetration electrodes 32 and 33 is formed on the base substrate wafer 40. Hereinafter, the penetration electrode forming step S30A will be described in detail. In the following description, although only the step of forming the penetration electrode 32 is described, the same applies to the step of forming the penetration electrode 33.

The penetration electrode forming step S30A includes a penetration hole forming step S32 of forming a recess portion for disposing the penetration electrode 32 on the base substrate wafer 40 and a rivet member disposing step S33 of inserting a rivet member into the penetration hole. The penetration electrode forming step S30A also includes a paste material filling step S35 of filling a paste material in the gap between the penetration hole and the core portion, and a baking step S37 of baking and curing the paste material. The penetration electrode forming step S30A also includes a polishing step S39 of polishing the second surface U of the base substrate wafer to remove the base portion and polishing the first surface L so that the core portion is exposed.

### Penetration Hole Forming Step

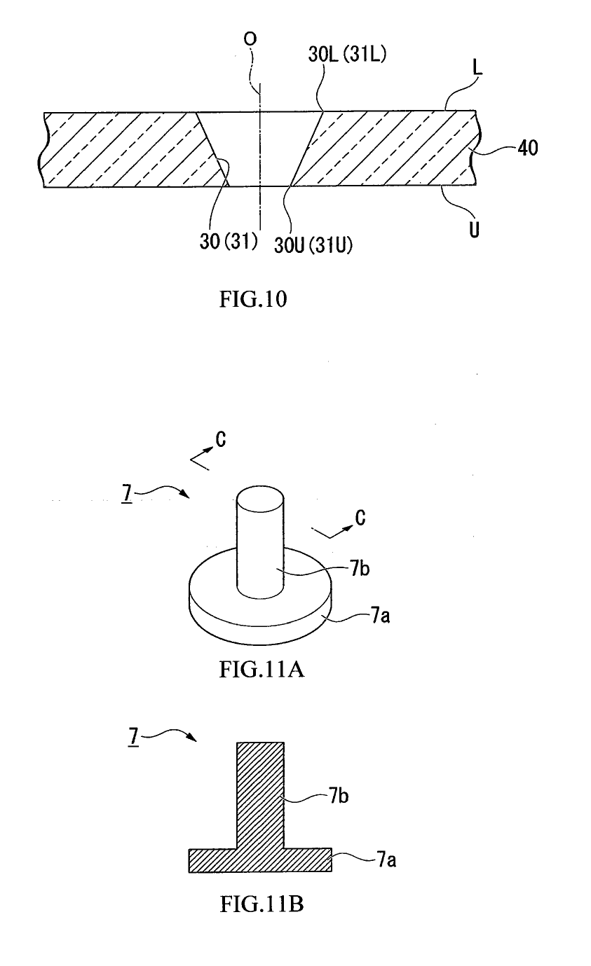

FIG. 10 is a diagram illustrating a penetration hole.

FIGS. 11A and 11B are diagrams illustrating a metal pin, in which FIG. 11A is a perspective view and FIG. 11B is a sectional view taken along the line C-C in FIG. 11A.

In the penetration electrode forming step S30A, a penetration hole forming step S32 is performed where the penetration hole 30 is formed in the base substrate wafer 40 so as to dispose the penetration electrode 32 (see FIG. 3). In the present embodiment, as shown in FIG. 10, the penetration hole 30 is formed by press working so that the outer shape of the opening thereof gradually decreases from the first surface L of the base substrate wafer 40 towards the second surface U.

As a specific example of the penetration hole forming step S32, first, a press mold is heated and pressed against the first surface L of the base substrate wafer 40. Here, a bowl-shaped recess portion is formed on the base substrate wafer 40 by a truncated conical projection formed on the press mold. After that, the second surface U of the base substrate wafer 40 is polished to remove the bottom surface of the recess portion, whereby the penetration hole 30 having a tapered inner surface is formed. In the present embodiment, although the cross section of the penetration hole 30 in the direction perpendicular to the central axis O has a circular shape, the cross section may have a rectangular shape, for example, by changing the shape of the projection on the press mold.

### Rivet Member Disposing Step

Subsequently, a rivet member disposing step S33 is performed where a rivet member is inserted into the penetration hole.

FIGS. 11A and 11B are diagrams illustrating the rivet member 7, in which FIG. 11A is a perspective view and FIG. 11B is a sectional view taken along the line C-C in FIG. 11A.

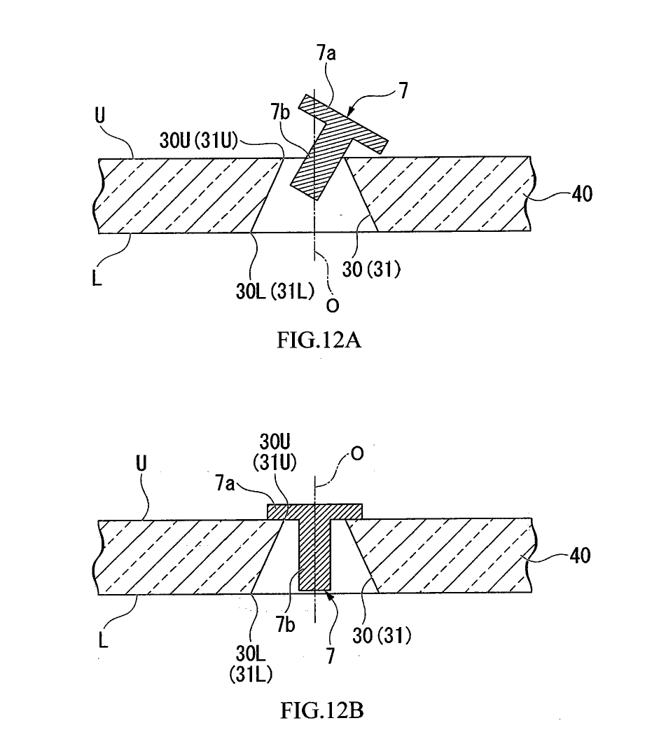

FIGS. 12A and 12B are diagrams illustrating a rivet member disposing step, in which FIG. 12A shows a state during the disposing and FIG. 12B shows a state after the disposing.

The rivet member 7 shown in FIGS. 11A and 11B is a conductive member formed of a metal material such as stainless steel, silver (Ag), an Ni alloy, Al, and particularly, is preferably formed of an alloy (42 alloy) in which the iron (Fe) content is 58 wt % and the Ni content is 42 wt %.

When the rivet member 7 is formed, first, a rod-like member having the same diameter as the core portion 7b is cut. After that, one end side of the rod-like member is processed by press working or forging to form the base portion 7a, and the other end side is cut, whereby the core portion 7b is formed. In the present embodiment, the base portion 7a has an approximately disk-like shape. In this way, the rivet member 7 having the base portion 7a and the core portion 7b are formed.

The outer shape of the base portion 7a in top view is larger than the outer shape of the core portion 7b in top view and is larger than the outer shape of a second opening 30U in top view. In the rivet member disposing step described later, the rivet member 7 is disposed in a state where the base portion 7a comes into contact with the second surface U of the base substrate wafer 40.

In the rivet member disposing step S33, as shown in FIGS. 12A and 12B, the core portion 7b of the rivet member 7 is disposed in the penetration hole 30. Specifically, the rivet member 7 is inserted from the second opening 30U of the base substrate wafer 40 so that the central axis of the core portion 7b is approximately identical to the central axis O of the penetration hole 30, whereby the core portion 7b is disposed at the inner side of the penetration hole 30. In the rivet member disposing step S33 of the present embodiment, the core portion 7b is inserted from the second opening 30U having a small diameter to block the second opening 30U with the base portion 7a so that the paste material can be filled from the first opening 30L having a large diameter in the paste material filling step S35 described later.

After the rivet member disposing step S33 is finished, a laminate material 70, for example, made of a paper tape is bonded to the second surface U side. In this way, it is possible to prevent falling of the rivet member 7 or leakage of the paste material in the paste material filling step described later. Then, the base substrate wafer 40 is turned upside down so that the first surface L side appears on the upper surface, and the paste material filling step described later is performed.

### Paste Material Filling Step

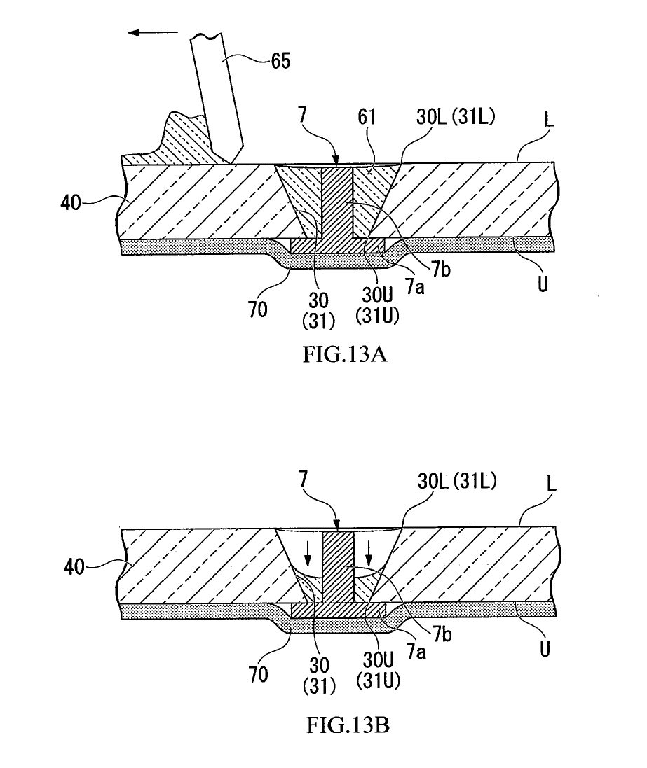

FIGS. 13A and 13B are diagrams illustrating a first paste material filling step S35A of the paste material filling step S35, in which FIG. 13A shows a state where a first paste material is being filled and FIG. 13B shows a state after the paste material is temporarily dried.

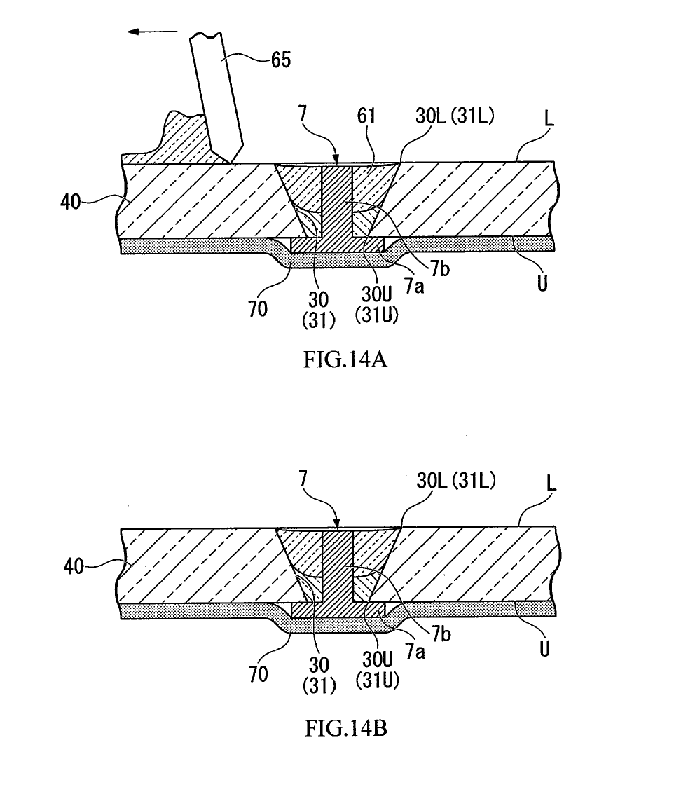

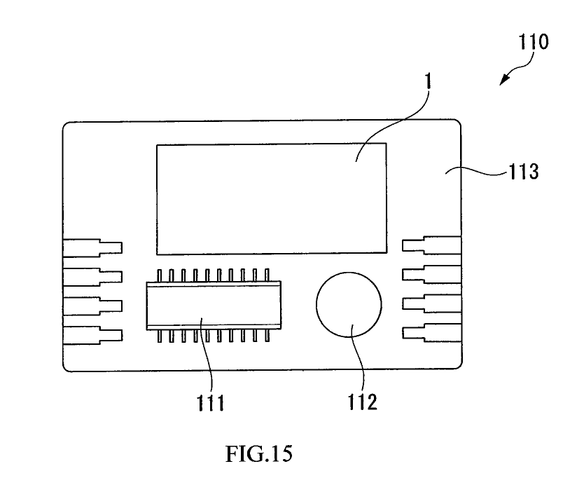

FIGS. 14A and 14B are diagrams illustrating a second paste material filling step S35B of the paste material filling step S35, in which FIG. 14A shows a state where a second paste material is being filled and FIG. 14B shows a state after the paste material is temporarily dried.

Subsequently, a paste material filling step S35 is performed where the first paste material 61 and the second paste material 63 are filled between the penetration hole 30 and the core portion 7b of the rivet member 7. The paste material filling step S35 includes a first paste material filling step S35A where the first paste material 61 is filled in the penetration hole 30, and a second paste material filling step S35B where after the first paste material 61 is temporarily dried, the second paste material 63 is filled in the penetration hole 30 to be overlapped on the first paste material 61.

In the present embodiment, the first and second paste materials 61 and 63 are paste-like glass frits which are mainly made up of a powder-like glass and an organic solvent which is a solvent. The viscosities of the first and second paste materials 61 and 63 are determined by the compounding ratio of the glass and the organic solvent. Specifically, the viscosity can be increased by increasing the compounding ratio of the glass and decreasing the compounding ratio of the organic solvent. Moreover, the viscosity can be decreased by decreasing the compounding ratio of the glass and increasing the compounding ratio of the organic solvent.

Here, the viscosity of the first paste material 61 is lower than the viscosity of the second paste material 63. Moreover, the compounding ratio of the glass in the first paste material 61 is lower than the compounding ratio of the glass in the second paste material 63, and the compounding ratio of the organic solvent in the first paste material 61 is higher than the compounding ratio of the glass in the second paste material 63. Specifically, the viscosity of the first paste material 61 is equal to or higher than 20 Pa·s and equal to or lower than 40 Pa·s, and the viscosity of the second paste material 63 is equal to or higher than 30 Pa·s and equal to or lower than 100 Pa·s. The viscosities of the respective paste materials are appropriately selected so that the viscosity of the first paste material 61 is lower than the viscosity of the second paste material 63.

### First Paste Material Filling Step

In the paste material filling step S35, first, a first paste material filling step S35A is performed where the first paste material 61 is filled in the penetration hole 30. In the present embodiment, the first paste material 61 is filled in the penetration hole 30 under a depressurized atmosphere. The first paste material filling step S35A will be described in detail below.

First, the base substrate wafer 40 is transferred and set in a chamber (not shown) of a vacuum screen printer (not shown) maintained under a depressurized atmosphere. After that, as shown in FIG. 13A, the first paste material 61 is deposited from the first surface L side of the base substrate wafer 40. The reason why the first paste material 61 is deposited from the first surface L side is because the outer shape of the first opening 30L on the first surface L side is larger than the outer shape of the second opening 30U on the second surface U side, and thus, the first paste material 61 can be easily filled in the penetration hole 30. At that time, since the inside of the chamber is depressurized to about 1 torr, the first paste material 61 is degassed, and bubbles included in the first paste material 61 are removed.

Subsequently, as shown in FIG. 13A, a squeegee 65 is moved along the first surface L while bringing the tip end of the squeegee 65 into contact with the first surface L of the base substrate wafer 40. In this way, the first paste material 61 is pushed and moved into the penetration hole 30 by the tip end of the squeegee 65, and the first paste material 61 is filled in the penetration hole 30. Here, the viscosity of the first paste material 61 is set to be as low as about 20 Pa·s, for example. Therefore, since the first paste material 61 has good mobility, the first paste material 61 can be dispersed over a wide area to every corner of the gap between the penetration hole 30 and the core portion 7b, and the occurrence of voids in the penetration electrode can be prevented. In addition, the base portion 7a of the rivet member 7 is in contact with the second surface U of the base substrate wafer 40. In this way, the first paste material 61 can be filled from the first surface L side while preventing the first paste material 61 from leaking from the second surface U side of the base substrate wafer 40.

After that, the first paste material 61 is temporarily dried. For example, after the base substrate wafer 40 is transferred into a chamber maintained at a constant temperature, the base substrate wafer 40 is maintained under an atmosphere of about 85° C. for about 30 minutes. In this way, as shown in FIG. 13B, the organic solvent included in the first paste material 61 is evaporated, and the volume of the first paste material 61 decreases. Moreover, since the compounding ratio of the organic solvent compounded in the first paste material 61 is high, when the organic solvent is evaporated through the temporary drying, the volume of the first paste material 61 will decrease greatly. After the temporary drying, the residues of the redundant first paste material 61 adhering on the first surface L of the base substrate wafer 40 are removed. The first paste material filling step S35A ends at this point in time.

### Second Paste Material Filling Step

In the paste material filling step S35, the second paste material filling step S35B is performed subsequently where the second paste material 63 is filled in the penetration hole 30 to be overlapped on the dried first paste material 61. As shown in FIG. 14A, similarly to the first paste material filling step S35A, under a depressurized atmosphere, the second paste material 63 is filled in the penetration hole 30 using the squeegee 65.

Here, the viscosity of the second paste material 63 is set to about 100 Pa·s, for example. Therefore, the viscosity of the second paste material 63 is higher than the viscosity of the first paste material 61 and has poorer mobility than the first paste material 61. However, through the first paste material filling step S35A described above, the first paste material 61 is dispersed and filled over a wide area to every corner of the gap between the penetration hole 30 and the core portion 7b in the vicinity of the second opening 30U having a small diameter. Therefore, in the second paste material filling step S35B, it is only necessary to fill the second paste material 63 in a relatively wide gap between the penetration hole 30 and the core portion 7b in the vicinity of the first opening 30L having a large diameter. Thus, even when the second paste material 63 has high viscosity, the second paste material 63 can be filled to every corner of the gap between the penetration hole 30 and the core portion 7b.

After that, similarly to the first paste material filling step S35A, the second paste material 63 is temporarily dried by leaving it under an atmosphere of about 85° C. for about 30 minutes. Since the compounding ratio of the organic solvent compounded in the second paste material 63 is low, even when the organic solvent is evaporated through the temporary drying, the volume of the second paste material 63 will be rarely reduced. After the temporary drying, the residues of the redundant second paste material 63 adhering on the first surface L of the base substrate wafer 40 are removed. The second paste material filling step S35B ends at this point in time.

### Baking Step

Subsequently, a baking step S37 is performed where the first and second paste materials 61 and 63 filled in the penetration hole 30 is baked. For example, after the base substrate wafer 40 is transferred to a baking furnace, the base substrate wafer 40 is maintained under an atmosphere of about 610° C. for about 30 minutes. In this way, the first and second paste materials 61 and 63 are solidified. As a result, the first and second paste materials 61 and 63 are solidified, and the penetration hole 30, the first and second paste materials 61 and 63, and the rivet member 7 are attached to each other, whereby the penetration electrode 32 can be formed.

Similarly to the temporary drying described above, since the organic solvent is also evaporated in the baking step S37, the volumes of the first and second paste materials 61 and 63 decrease. However, since the ratio of the organic solvent compounded in the second paste material 63 is low, the decrease in its volume during the baking is small. In addition, since the organic solvent included in the first and second paste materials 61 and 63 is evaporated to some extent through the temporary drying, the decrease in the volumes of the first and second paste materials 61 and 63 is small. Therefore, no large depressions will be formed on the surface of the penetration electrode after the baking.

### Polishing Step

Subsequently, a polishing step S39 is performed where the first and second surfaces L and U of the base substrate wafer 40 is polished. By polishing the first surface L, it is possible to make the first surface L flat and expose the tip end of the core portion 7b. Moreover, by polishing the second surface U, it is possible to remove the base portion 7a and allow the core portion 7b to remain inside the cylindrical member 6. As a result, it is possible to make the surface of the base substrate wafer 40 approximately flush with both ends of the rivet member 7 and obtain a plurality of pairs of penetration electrodes 32 shown in FIG. 3. The penetration electrode forming step S30A ends at a point in time when the polishing step S39 is performed.

After that, returning to FIG. 9, a lead-out electrode forming step S40 is performed where a plurality of lead-out electrodes 36 and 37 is formed so as to be electrically connected to the penetration electrodes, respectively. In addition, tapered bumps made of gold or the like are formed on the lead-out electrodes 36 and 37. In FIG. 9, illustrations of the bumps are omitted for better illustration of the drawing. The base substrate wafer manufacturing step S30 ends at this point in time.

### Piezoelectric Vibrator Assembling Step Subsequent to Mounting Step S50

Subsequently, a mounting step S50 is performed where the piezoelectric vibrating reeds 4 are bonded to the lead-out electrodes 36 and 37 of the base substrate wafer 40 by the bumps B. Specifically, the base portions 12 of the piezoelectric vibrating reeds 4 are placed on the bumps B, and the piezoelectric vibrating reeds 4 are pressed against the bumps B while heating the bumps B to a predetermined temperature. In this way, as shown in FIG. 3, the base portions 12 are mechanically fixed to the bumps B in a state where the vibrating arms 10 and 11 of the piezoelectric vibrating reed 4 are floated from the second surface U of the base substrate wafer 40. Moreover, the mount electrodes 16 and 17 are electrically connected to the lead-out electrodes 36 and 37.

After the mounting of the piezoelectric vibrating reeds 4 is completed, as shown in FIG. 9, a superimposition step S60 is performed where the lid substrate wafer 50 is superimposed onto the base substrate wafer 40. Specifically, the two wafers 40 and 50 are aligned at a correct position using reference marks (not shown) or the like as indices. In this way, the piezoelectric vibrating reed 4 mounted on the base substrate wafer 40 is accommodated in the cavity C which is surrounded by the recess portion 3a of the lid substrate wafer 50 and the base substrate wafer 40.

After the superimposition step S60 is performed, a bonding step S70 is performed where the two superimposed wafers 40 and 50 are inserted into an anodic bonding machine (not shown) to achieve anodic bonding under a predetermined temperature atmosphere with application of a predetermined voltage. Specifically, a predetermined voltage is applied between the bonding film 35 and the base substrate wafer 40. Then, an electrochemical reaction occurs at an interface between the bonding film 35 and the base substrate wafer 40, whereby they are closely and tightly adhered and anodically bonded. In this way, the piezoelectric vibrating reed 4 can be sealed in the cavity C, and a wafer assembly 60 in which the base substrate wafer 40 and the lid substrate wafer 50 are bonded to each other can be obtained as shown in FIG. 9. In FIG. 9, for better understanding of the drawing, the wafer assembly 60 is illustrated in an exploded state, and illustration of the bonding film 35 is omitted from the lid substrate wafer 50.

Subsequently, an outer electrode forming step S80 is performed where a conductive material is patterned onto the first surface L of the base substrate wafer 40 so as to form a plurality of pairs of outer electrodes 38 and 39 (see FIG. 3) which is electrically connected to the pair of penetration electrodes 32 and 33. Through this step, the piezoelectric vibrating reed 4 is electrically connected to the outer electrodes 38 and 39 through the penetration electrodes 32 and 33.

Subsequently, a fine tuning step S90 is performed on the wafer assembly 60 where the frequencies of the individual piezoelectric vibrators sealed in the cavities C are tuned finely to fall within a predetermined range. Specifically, a predetermined voltage is continuously applied to the outer electrodes 38 and 39 shown in FIG. 4 to allow the piezoelectric vibrating reeds 4 to vibrate, and the vibration frequency is measured. In this state, a laser beam is irradiated onto the base substrate wafer 40 from the outer side so as to evaporate the fine tuning film 21b of the weight metal film 21 shown in FIGS. 5 and 6. In this way, since the weight on the tip end sides of the pair of vibrating arms 10 and 11 decreases, the frequency of the piezoelectric vibrating reed 4 increases. By so doing, the frequency of the piezoelectric vibrator can be finely tuned so as to fall within the range of the nominal frequency.

After the fine tuning of the frequency is completed, a cutting step S100 is performed where the bonded wafer assembly 60 is cut along the cutting line M shown in FIG. 9. Specifically, first, a UV tape is attached on the surface of the base substrate wafer 40 of the wafer assembly 60. Subsequently, a laser beam is irradiated along the cutting line M from the side of the lid substrate wafer 50 (scribing). Subsequently, the wafer assembly 60 is divided and cut along the cutting line M by a cutting blade pressing against the surface of the UV tape (breaking). After that, the UV tape is separated by irradiation of UV light. In this way, it is possible to divide the wafer assembly 60 into a plurality of piezoelectric vibrators. The wafer assembly 60 may be cut by other methods such as dicing.

Moreover, the fine adjustment step S90 may be performed after cutting the wafer body into pieces of individual piezoelectric vibrators in the cutting step S100. However, as described above, since the fine adjustment can be performed in a state of the wafer body 60 by performing the fine adjustment step S90 first, a plurality of piezoelectric vibrators can be finely adjusted more efficiently. This is preferable since the throughput can be improved.

Then, an inner electrical property test S110 is performed. That is, resonance frequency, resonant resistance value, drive level characteristics (exciting power dependency of resonance frequency and resonant resistance value), and the like of the piezoelectric vibrating reed 4 are checked by measurement. Moreover, an insulation resistance characteristic and the like are checked together. Finally, visual inspection of the piezoelectric vibrator is performed to finally check the dimension, quality, and the like. Thus, the manufacturing of the piezoelectric vibrator ends.

According to the present embodiment, as shown in FIGS. 14A and 14B, since the first paste material 61 having a low viscosity is filled first, the first paste material 61 can be dispersed over a wide area to every corner of the inner portions of the penetration holes 30 and 31. Therefore, since the occurrence of voids in the penetration electrode can be suppressed, it is possible to maintain the airtightness of the cavity in a favorable state. However, since the ratio of a solvent or the like compounded in the first paste material 61 having a low viscosity is high, the decrease in its volume during curing is large. In contrast, according to the present embodiment, the second paste material 63 having a high viscosity is filled so as to be overlapped on the first paste material 61. The ratio of a solvent or the like compounded in the second paste material 63 is low as compared to the first paste material 61, and the decrease in its volume during curing is small. Therefore, it is possible to suppress the occurrence of depressions on the surface of the penetration electrode after curing and form the penetration electrode without conduction defects.

### Oscillator

Next, an oscillator according to another embodiment of the invention will be described with reference to FIG. 15.

In an oscillator 110 according to the present embodiment, the piezoelectric vibrator 1 is used as an oscillating piece electrically connected to an integrated circuit 111, as shown in FIG. 15. The oscillator 110 includes a substrate 113 on which an electronic component 112, such as a capacitor, is mounted. The integrated circuit 111 for an oscillator is mounted on the substrate 113, and the piezoelectric vibrator 1 is mounted near the integrated circuit 111. The electronic component 112, the integrated circuit 111, and the piezoelectric vibrator 1 are electrically connected to each other by a wiring pattern (not shown). In addition, each of the constituent components is molded with a resin (not shown).

In the oscillator 110 configured as described above, when a voltage is applied to the piezoelectric vibrator 1, the piezoelectric vibrating reed in the piezoelectric vibrator 1 vibrates. This vibration is converted into an electrical signal due to the piezoelectric property of the piezoelectric vibrating reed and is then input to the integrated circuit 111 as the electrical signal. The input electrical signal is subjected to various kinds of processing by the integrated circuit 111 and is then output as a frequency signal. In this way, the piezoelectric vibrator 1 functions as an oscillating piece.

Moreover, by selectively setting the configuration of the integrated circuit 111, for example, an RTC (real time clock) module, according to the demands, it is possible to add a function of controlling the operation date or time of the corresponding device or an external device or of providing the time or calendar in addition to a single functional oscillator for a clock.

According to the present embodiment, since the oscillator 110 includes the piezoelectric vibrator 1 which is manufactured by a manufacturing method capable of securing reliable conduction of the penetration electrode while maintaining the airtightness of the cavity, the oscillator 110 having excellent performance and superior reliability can be provided.

### Electronic Apparatus

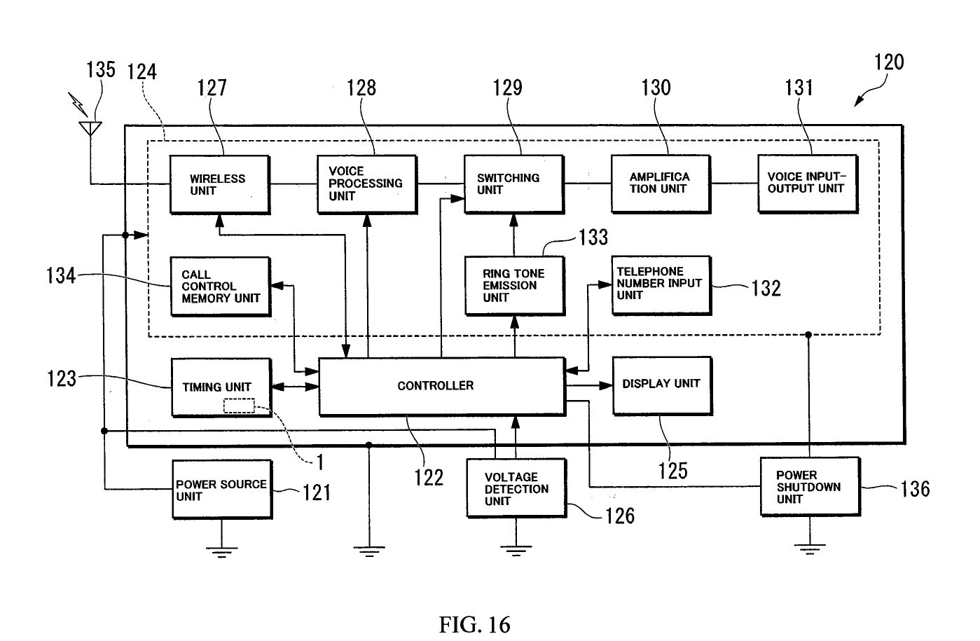

Next, an electronic apparatus according to another embodiment of the invention will be described with reference to FIG. 16. In addition, a portable information device 120 including the piezoelectric vibrator 1 will be described as an example of an electronic apparatus.

The portable information device 120 according to the present embodiment is represented by a mobile phone, for example, and has been developed and improved from a wristwatch in the related art. The portable information device 120 is similar to a wristwatch in external appearance, and a liquid crystal display is disposed in a portion equivalent to a dial pad so that a current time and the like can be displayed on this screen. Moreover, when it is used as a communication apparatus, it is possible to remove it from the wrist and to perform the same communication as a mobile phone in the related art with a speaker and a microphone built in an inner portion of the band. However, the portable information device 120 is very small and light compared with a mobile phone in the related art.

Next, the configuration of the portable information device 120 according to the present embodiment will be described. As shown in FIG. 16, the portable information device 120 includes the piezoelectric vibrator 1 and a power supply section 121 for supplying power. The power supply section 121 is formed of a lithium secondary battery, for example. A control section 122 which performs various kinds of control, a clock section 123 which performs counting of time and the like, a communication section 124 which performs communication with the outside, a display section 125 which displays various kinds of information, and a voltage detecting section 126 which detects the voltage of each functional section are connected in parallel to the power supply section 121. In addition, the power supply section 121 supplies power to each functional section.

The control section 122 controls an operation of the entire system. For example, the control section 122 controls each functional section to transmit and receive the audio data or to measure or display a current time. In addition, the control section 122 includes a ROM in which a program is written in advance, a CPU which reads and executes a program written in the ROM, a RAM used as a work area of the CPU, and the like.

The clock section 123 includes an integrated circuit, which has an oscillation circuit, a register circuit, a counter circuit, and an interface circuit therein, and the piezoelectric vibrator 1. When a voltage is applied to the piezoelectric vibrator 1, the piezoelectric vibrating reed vibrates, and this vibration is converted into an electrical signal due to the piezoelectric property of crystal and is then input to the oscillation circuit as the electrical signal. The output of the oscillation circuit is binarized to be counted by the register circuit and the counter circuit. Then, a signal is transmitted to or received from the control section 122 through the interface circuit, and current time, current date, calendar information, and the like are displayed on the display section 125.

The communication section 124 has the same function as a mobile phone in the related art, and includes a wireless section 127, an audio processing section 128, a switching section 129, an amplifier section 130, an audio input/output section 131, a telephone number input section 132, a ring tone generating section 133, and a call control memory section 134.

The wireless section 127 transmits/receives various kinds of data, such as audio data, to/from the base station through an antenna 135. The audio processing section 128 encodes and decodes an audio signal input from the wireless section 127 or the amplifier section 130. The amplifier section 130 amplifies a signal input from the audio processing section 128 or the audio input/output section 131 up to a predetermined level. The audio input/output section 131 is formed by a speaker, a microphone, and the like, and amplifies a ring tone or incoming sound or collects the sound.

In addition, the ring tone generating section 133 generates a ring tone in response to a call from the base station. The switching section 129 switches the amplifier section 130, which is connected to the audio processing section 128, to the ring tone generating section 133 only when a call arrives, so that the ring tone generated in the ring tone generating section 133 is output to the audio input/output section 131 through the amplifier section 130.

In addition, the call control memory section 134 stores a program related to incoming and outgoing call control for communications. Moreover, the telephone number input section 132 includes, for example, numeric keys from 0 to 9 and other keys. The user inputs a telephone number of a communication destination by pressing these numeric keys and the like.

The voltage detecting section 126 detects a voltage drop when a voltage, which is applied from the power supply section 121 to each functional section, such as the control section 122, drops below the predetermined value, and notifies the control section 122 of the detection. In this case, the predetermined voltage value is a value which is set beforehand as a lowest voltage necessary to operate the communication section 124 stably. For example, it is about 3 V. When the voltage drop is notified from the voltage detecting section 126, the control section 122 disables the operation of the wireless section 127, the audio processing section 128, the switching section 129, and the ring tone generating section 133. In particular, the operation of the wireless section 127 that consumes a large amount of power should be necessarily stopped. In addition, a message informing that the communication section 124 is not available due to insufficient battery power is displayed on the display section 125.

That is, it is possible to disable the operation of the communication section 124 and display the notice on the display section 125 by the voltage detecting section 126 and the control section 122. This message may be a character message. Or as a more intuitive indication, a cross mark (X) may be displayed on a telephone icon displayed at the top of the display screen of the display section 125.

In addition, the function of the communication section 124 can be more reliably stopped by providing a power shutdown section 136 capable of selectively shutting down the power of a section related to the function of the communication section 124.

According to the present embodiment, since the portable information device 120 includes the piezoelectric vibrator 1 which is manufactured by a manufacturing method capable of securing reliable conduction of the penetration electrode while maintaining the airtightness of the cavity, the portable information device 120 having excellent performance and superior reliability can be provided.

### Radio-Controlled Timepiece

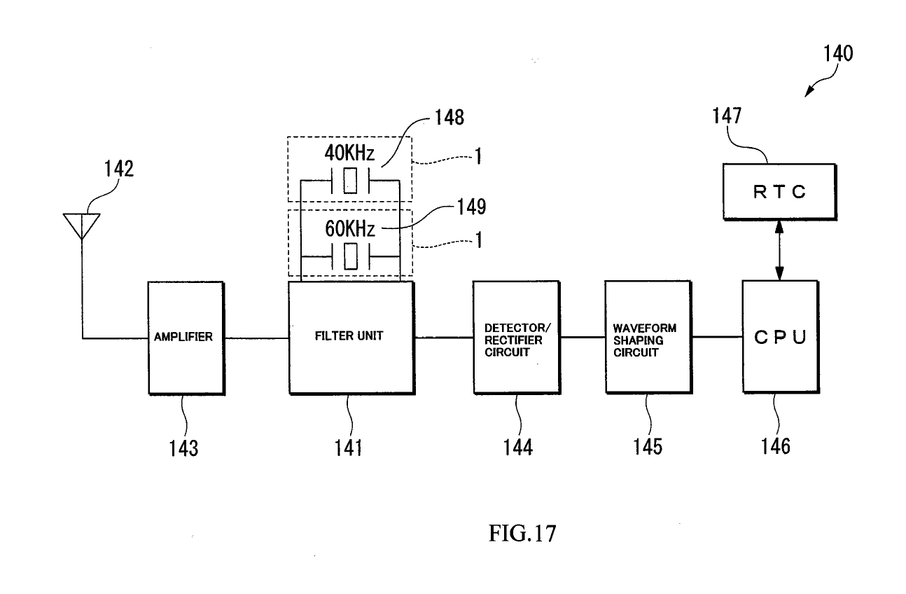

Next, a radio-controlled timepiece according to still another embodiment of the invention will be described with reference to FIG. 17.

As shown in FIG. 17, a radio-controlled timepiece 140 according to the present embodiment includes the piezoelectric vibrators 1 electrically connected to a filter section 141. The radio-controlled timepiece 140 is a clock with a function of receiving a standard radio wave including the clock information, automatically changing it to the correct time, and displaying the correct time.

In Japan, there are transmission centers (transmission stations) that transmit a standard radio wave in Fukushima Prefecture (40 kHz) and Saga Prefecture (60 kHz), and each center transmits the standard radio wave. A long wave with a frequency of, for example, 40 kHz or 60 kHz has both a characteristic of propagating along the land surface and a characteristic of propagating while being reflected between the ionospheric layer and the land surface, and therefore has a propagation range wide enough to cover the entire area in Japan through the two transmission centers.

Hereinafter, the functional configuration of the radio-controlled timepiece 140 will be described in detail.

An antenna 142 receives a long standard radio wave with a frequency of 40 kHz or 60 kHz. The long standard radio wave is obtained by performing AM modulation of the time information, which is called a time code, using a carrier wave with a frequency of 40 kHz or 60 kHz. The received long standard wave is amplified by an amplifier 143 and is then filtered and synchronized by the filter section 141 having the plurality of piezoelectric vibrators 1.

In the present embodiment, the piezoelectric vibrators 1 include crystal vibrator sections 148 and 149 having resonance frequencies of 40 kHz and 60 kHz, respectively, which are the same frequencies as the carrier frequency.

In addition, the filtered signal with a predetermined frequency is detected and demodulated by a detection and rectification circuit 144.

Then, the time code is extracted by a waveform shaping circuit 145 and counted by the CPU 146. The CPU 146 reads the information including the current year, the total number of days, the day of the week, the time, and the like. The read information is reflected on an RTC 147, and the correct time information is displayed.

Because the carrier wave is 40 kHz or 60 kHz, a vibrator having the tuning fork structure described above is suitable for the crystal vibrator sections 148 and 149.

Moreover, although the above explanation has been given for the case in Japan, the frequency of a long standard wave is different in other countries. For example, a standard wave of 77.5 kHz is used in Germany. Therefore, when the radio-controlled timepiece 140 which is also operable in other countries is assembled in a portable device, the piezoelectric vibrator 1 corresponding to frequencies different from the frequencies used in Japan is necessary.

According to the present embodiment, since the radio-controlled timepiece 140 includes the piezoelectric vibrator 1 which is manufactured by a manufacturing method capable of securing reliable conduction of the penetration electrode while maintaining the airtightness of the cavity, the radio-controlled timepiece 140 having excellent performance and superior reliability can be provided.

The present invention is not limited to the above-described embodiments.

In the present embodiment, the method of manufacturing a package according to the present invention has been described by way of an example of a piezoelectric vibrator using a tuning-fork type piezoelectric vibrating reed. However, the method of manufacturing a package according to the present invention may be applied to a piezoelectric vibrator using an AT-cut type piezoelectric vibrating reed (a thickness-shear type vibrating reed).

In the present embodiment, the penetration hole has a tapered inner surface in a cross section including the central axis of the penetration hole. However, the inner surface of the penetration hole may have a straight shape rather than the tapered shape. However, the present embodiment is superior in that the first and second paste materials can be easily filled in the gap between the penetration hole and the core portion.

In the present embodiment, the penetration electrode is formed by disposing the core portion of the conductive rivet member in the penetration hole and then filling the glass frit in the gap between the penetration hole and the core portion. However, the penetration electrode may be formed by filling a conductive paste material made up of a conductive member such as Ag powder or Au—Sn powder and a solvent or the like as the first and second paste materials in the penetration hole. However, the penetration electrode of the present embodiment is superior in that the occurrence of depressions on the surface of the penetration electrode after the curing can be prevented, and the conduction between the piezoelectric vibrating reed and the outer electrode can be secured.

In the present embodiment, the base portion and the core portion are formed in a circular shape in the cross section vertical to the axis of the core portion. However, either or both of the base portion and the core portion of the rivet member may be formed in a non-circular shape in the cross section vertical to the axis of the core portion.

In the present embodiment, a piezoelectric vibrator is manufactured by sealing a piezoelectric vibrating reed in a package using the method of manufacturing a package according to the present invention. However, a device other than the piezoelectric vibrator may be manufactured by sealing an electronic component other than the piezoelectric vibrating reed in a package.

In the present embodiment, each of the first and second paste material filling steps is performed only once in the paste material filling step. However, after the second paste material filling step is performed, the paste material may be filled in an overlapped manner. In this way, it is possible to prevent the occurrence of depressions in a more reliable manner.

What is claimed is:

1. A method for producing piezoelectric vibrators, comprising:
(a) defining a plurality of first substrates on a first wafer and a plurality of second substrates on a second wafer;
(b) forming a pair of through-holes in a respective at least some of the first substrates on the first wafer;
(c) filling at least some of the through-holes with first and second types of fillers in layers, wherein the first and second types of fillers have different viscosities;
(d) layering the first and second wafers such that at least some of the first substrates substantially coincide respectively with at least some of the corresponding second substrates, wherein a piezoelectric vibrating strip is secured in a respective at least some of coinciding first and second substrates;
(e) cutting off a respective at least some of packages made of coinciding first and second substrates.

2. The method according to claim 1, wherein the first and second types of fillers both comprise glass frit paste.

3. The method according to claim 2, wherein the first and second types of fillers further comprise an organic solvent.

4. The method according to claim 3, wherein the first and second types of fillers have different composition ratios of the organic solvent to have different viscosities.

5. The method according to claim 1, wherein the first type of filler has a viscosity of about 20 Pa·s to about 40 Pa·s, and the second type of filler has a viscosity of about 30 Pa·s to about 100 Pa·s, wherein the viscosity of the first type of filler is always lower than that of the second type of filler.

6. The method according to claim 1, wherein filling at least some of the through-holes with first and second types of fillers in layers comprises first placing the first type of filler in at least some of the through-holes and then placing the second type of filler in at least some of the through-holes in which the first type of filler is placed.

7. The method according to claim 6, wherein placing the first type of filler in at least some of the through-holes and placing the second type of filler in at least some of the through-holes in which the first type of filler is placed each comprise squeegeeing the filler in the through-holes in a low pressure atmosphere.

8. The method according to claim 7, wherein the low pressure atmosphere is about 1 torr.

9. The method according to claim 6, wherein placing the first type of filler in at least some of the through-holes and placing the second type of filler in at least some of the through-holes in which the first type of filler is placed each comprise drying the filler in the through-holes.

10. The method according to claim 9, wherein drying the filler comprising heating the filler at about 85° C.

11. The method according to claim 1, further comprising baking the first wafer between steps (c) and (d).

12. The method according to claim 11, wherein baking the first wafer comprises heating the first wafer at a temperature of about 610° C.

13. The method according to claim 12, wherein heating the first wafer comprises heating the first wafer for about 30 minutes.

14. A piezoelectric vibrator comprising:
a hermetically closed casing comprising first and second substrates with a cavity inside, the first substrate being formed with a pair of through-holes which are closed with layers of first and second types of fillers, wherein the first and second types of fillers are made of materials with different viscosities being hardened by baking; and
a piezoelectric vibrating strip secured inside the cavity and electrically connected via a conductive pattern to the fillers in the through-holes.

15. An oscillator comprising the piezoelectric vibrator defined in claim 14.

16. An electronic device comprising a clock connected with the piezoelectric vibrator defined in claim 15.

17. An electronic device comprising a filter connected with the piezoelectric vibrator defined in claim 16.
